(19) United States
(12) Patent Application Publication
(10) Pub. No.: US 2026/0160496 A1
(43) Pub. Date: Jun. 11, 2026

(54) PLASMA ASSISTED METAL OXIDE REDUCTION DURING DIE-TO-WAFER ANNEAL

(71) Applicant: Tokyo Electron Limited, Tokyo (JP)

(72) Inventors: Angelique Raley, Albany, NY (US); Arkalgud Sitaram, Albany, NY (US)

(21) Appl. No.: 18/970,088

(22) Filed: Dec. 5, 2024

(51) Int. Cl. H01L 23/00; F27B 17/00; H01J 37/32

(52) U.S. Cl. CPC F27B 17/0025; H01J 37/32449; H01J 37/32816; H10W 80/314; H10W 80/327

(57) ABSTRACT

A method for making a semiconductor device can include picking and placing a top die onto a bottom die on a wafer such that a first set of operational contacts of the bottom die are aligned with and physically contacting a second set of operational contacts of the top die, and such that a first set of test contacts are exposed and not fully covered by the top die, and annealing the wafer to induce bonding of the second set of operational contacts of the top die with the first set of operational contacts of the bottom die in a plasma-equipped furnace chamber while exciting a plasma along with flowing gas including nitrogen and hydrogen to hinder oxidation of metal, such as copper, in the first set of test contacts during the annealing.

### TECHNICAL FIELD

The present disclosure relates generally to methods for manufacturing semiconductor devices, and more particularly, processes for plasma assisted metal oxide reduction during die-to-wafer anneal for manufacturing semiconductor devices.

### BACKGROUND

In semiconductor packaging during manufacturing of semiconductor devices, die-to-wafer (D2W) bonding can be used to bond individual or already singulated dies onto a larger wafer having a plurality of unsingulated dies, respectively. For example, D2W bonding can be used in heterogeneous integration where different types of dies, such as logic and memory chips, or such as analog and digital chips, are combined into a single package.

For D2W bonding, the singulated dies are placed on the wafer with high precision to align contacts to ensure electrical conductivity between respective contacts exposed on the surfaces of the dies and the wafer. The dies can be bonded to the wafer using a variety of techniques, including but not limited to thermal compression (using heat and pressure), adhesive bonding (using conductive glue), soldering (using heat to melt or reflow solder at the contact junctions), or copper-to-copper direct bonding (using heat to anneal the copper surface for direct metallic bonding by the diffusion of copper across the surface contact interface of two copper contacts).

During copper-to-copper direct bonding, the annealing of the copper can cause exposed copper test contacts (or probe contacts) to be oxidized. Conventional techniques can use a high-pressure flow (and/or high volumetric flow rate) of nitrogen and hydrogen to hinder the exposed copper from oxidizing, but such conventional techniques use large volumes of nitrogen and hydrogen, which can be expensive because it can require a large supply of such gases, while annealing only one wafer at a time. Thus, there is a need for improving the efficiency and reduce the costs of copper-to-copper direct bonding for D2W bonding.

### SUMMARY

In accordance with an embodiment of the present disclosure, a method of manufacturing semiconductor devices can include: providing a first wafer including a bottom die, where the bottom die includes a first integrated circuit formed therein, where the bottom die includes a first set of operational contacts and a first set of test contacts, where the first set of operational contacts and the first set of test contacts are exposed on a top surface of the bottom die, and where the first set of test contacts include a metal; providing a top die from a second wafer, where the second wafer is different than the first wafer, where the top die includes a second integrated circuit formed therein, where the top die includes a second set of operational contacts, and where the second set of operational contacts are exposed on a bottom surface of the top die; picking and placing the top die onto the bottom die such that the second set of operational contacts of the top die are aligned with and physically contacting the first set of operational contacts of the bottom die, and such that the first set of test contacts are exposed and not fully covered by the top die; and annealing the first wafer to induce bonding of the second set of operational contacts of the top die with the first set of operational contacts of the bottom die in a plasma-equipped furnace chamber while exciting a plasma in the plasma-equipped furnace chamber along with flowing of a chamber gas including nitrogen and hydrogen to hinder oxidation of the metal of the first set of test contacts during the annealing.

In accordance with an embodiment of the present disclosure, a method of manufacturing semiconductor devices can include: providing a first wafer including a plurality of bottom dies, where each of the plurality of bottom dies includes a first integrated circuit formed therein, where each of the plurality of bottom dies includes a first set of operational contacts and a first set of test contacts, where the first set of operational contacts and the first set of test contacts are exposed on a top surface of each of the plurality of bottom dies, and where the first set of test contacts of each of the plurality of bottom dies include a metal; providing a plurality of top dies from a second one or more wafers, where the second one or more wafers is different than the first wafer, where each of the plurality of top dies includes a second integrated circuit formed therein, where each of the plurality of top dies includes a second set of operational contacts, and where the second set of operational contacts are exposed on a bottom surface of each of the plurality of top dies; picking and placing the plurality of top dies onto the plurality of bottom dies, respectively, such that the second set of operational contacts of each of the plurality of top dies are aligned with and physically contacting the first set of operational contacts of each of the plurality of bottom dies, respectively, and such that the first set of test contacts of each of the plurality of bottom dies are exposed and not fully covered by the plurality of top dies; and annealing the first wafer to induce bonding of the second set of operational contacts of each of the plurality of top dies with the first set of operational contacts of each of the plurality of bottom dies, respectively, in a plasma-equipped furnace chamber while exciting a plasma in the plasma-equipped furnace chamber along with flowing of a chamber gas including nitrogen and hydrogen to hinder oxidation of the metal of the first set of test contacts of the plurality of bottom dies during the annealing.

In accordance with an embodiment of the present disclosure, a method of manufacturing semiconductor devices can include: providing a first wafer including a bottom die, where the bottom die includes a first integrated circuit formed therein, where the bottom die includes a first set of operational contacts and a first set of test contacts, where the first set of operational contacts and the first set of test contacts are exposed on a top surface of the bottom die, and where the first set of test contacts include a metal; providing a top die from a second wafer, where the second wafer is different than the first wafer, where the top die includes a second integrated circuit formed therein, where the top die includes a second set of operational contacts, and where the second set of operational contacts are exposed on a bottom surface of the top die; performing a first annealing of the first wafer in a plasma-equipped furnace chamber while exciting a first plasma in the plasma-equipped furnace chamber along with flowing of a first chamber gas including nitrogen and hydrogen to remove surface oxidation from the first set of operational contacts and the first set of test contacts; picking and placing the top die onto the bottom die such that the second set of operational contacts of the top die are aligned with and physically contacting the first set of operational contacts of the bottom die, and such that the first set of test contacts are exposed and not fully covered by the top die; and performing a second annealing of the first wafer to induce bonding of the second set of operational contacts of the top die with the first set of operational contacts of the bottom die in the plasma-equipped furnace chamber while exciting a second plasma in the plasma-equipped furnace chamber along with flowing of a second chamber gas including nitrogen and hydrogen to hinder oxidation of the metal of the first set of test contacts during the second annealing.

### BRIEF DESCRIPTION OF THE DRAWINGS

For a more complete understanding of example embodiments of the present disclosure, and the advantages thereof, reference is now made to the following descriptions taken in conjunction with the accompanying drawings, in which:

FIG. 1 is a cross-section view for a portion of a wafer illustrating an intermediate structure during a pick-and-place operation for die-to-wafer bonding in a method of manufacturing semiconductor devices according to an embodiment of the present disclosure;

FIG. 2 is an enlarged top view of a top die placed on a bottom die, according to an embodiment of the present disclosure;

FIG. 3A is an enlarged cross-section of area A of FIG. 2 taken along line B-B, prior to annealing, according to an embodiment of the present disclosure;

FIG. 3B is an enlarged cross-section of area A of FIG. 2 taken along line B-B, after annealing, according to an embodiment of the present disclosure;

FIG. 4 is a simplified diagram illustrating multiple wafers being annealed together in a single plasma-equipped furnace chamber, according to an embodiment of the present disclosure;

FIG. 5 is a flowchart illustrating a method for manufacturing semiconductor devices according to an embodiment of the present disclosure;

FIG. 6 is a flowchart illustrating a method for manufacturing semiconductor devices according to an embodiment of the present disclosure;

FIG. 7 is a flowchart illustrating a method for manufacturing semiconductor devices according to an embodiment of the present disclosure; and

FIG. 8 is a diagram illustrating a plasma-equipped furnace chamber for implementing methods of manufacturing semiconductor devices according to some embodiments of the present disclosure.

### DETAILED DESCRIPTION OF ILLUSTRATIVE EMBODIMENTS

Referring now to the drawings, in which like reference numbers can be used herein to designate like or similar elements throughout the various views, illustrative and example embodiments are shown and described. The figures are not drawn to scale, and in some instances the drawings are exaggerated or simplified in places for illustrative purposes. One of ordinary skill in the art can appreciate many possible applications and variations for other embodiments based on the following illustrative and example embodiments provided in the present disclosure.

Some example embodiments of the present disclosure are described in more detail below with reference to the drawings of the present disclosure, to describe some example variations for some embodiments of the present disclosure. Other embodiments can also be understood from the entirety of the specification and the claims filed herein.

In the present disclosure, terms such as “first”, “second”, and the like, may be used to describe various components, but the components are not necessarily limited by such terms, for example, regarding nature, order, sequence, importance, or number of such components possible in an embodiment. Such terms can be used merely for the purpose of distinguishing one component from other components in a given embodiment or group of embodiments. For example, a first component may be referred to as a second component, and similarly, a second component may also be referred to as a first component without departing from the scopes of rights according to the present disclosure.

In the present disclosure, certain elements may be discussed as, referred to, and actually plural, but only shown as a singular example in the drawings, even though that single example can be among a set of a plurality. Similarly, certain elements may be discussed, referred to, and shown as singular, but may be plural or may be part of a set of a plurality of the same. Given that a structure and feature is typically repeated many times in a semiconductor device, one of ordinary skill in the art to which the present disclosure pertains can realize and understand such alternating between singular and plural. And, even though a limited example number of plural elements may be shown, one of ordinary skill in the art to which the present disclosure pertains can realize and understand that such limited example number of plural elements in an example embodiment can be ten, tens, thousands, or even millions in count an actual implementation for an embodiment of the present disclosure.

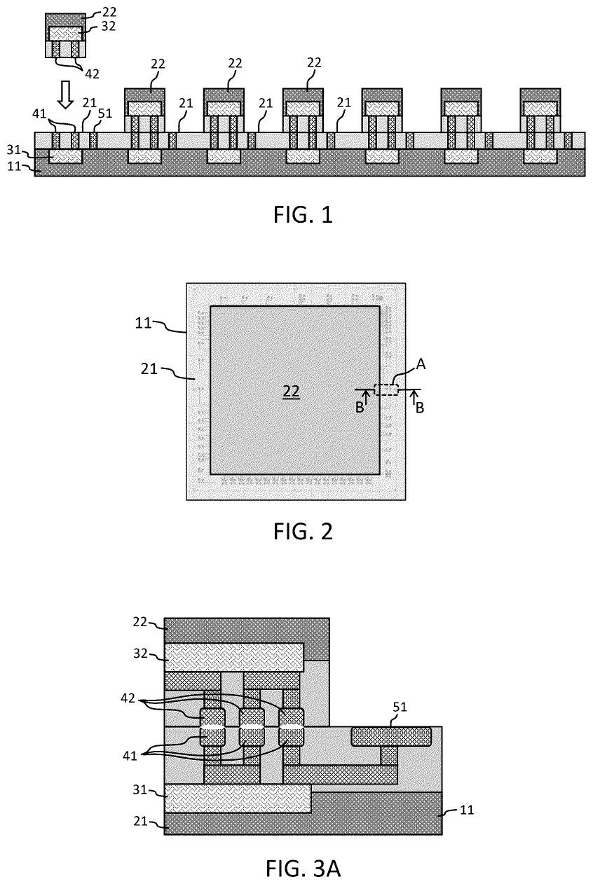

Some example embodiments of the present disclosure are described below with reference to FIGS. 1-8. Other embodiments can also be understood from the entirety of the specification as well as the claims herein.

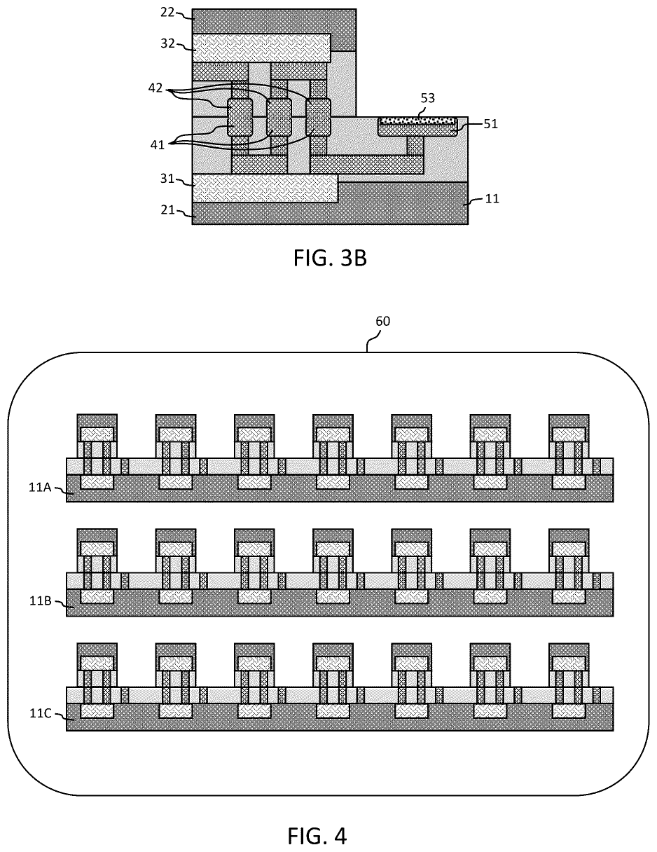

Die-to-wafer (D2W) bonding processes and techniques can be used for connecting multiple dies and packaging of semiconductor devices. FIG. 1 is a cross-section view for a portion of a wafer 11 illustrating an intermediate structure during a pick-and-place operation for D2W bonding in a method of manufacturing semiconductor devices according to an embodiment of the present disclosure. FIG. 2 is an enlarged top view of a top die 22 placed on a bottom die 21, according to an embodiment of the present disclosure. FIG. 3A is an enlarged cross-section of area A of FIG. 2 taken along line B-B, prior to an annealing operation for D2W bonding, according to an embodiment of the present disclosure. FIG. 3B is an enlarged cross-section of area A of FIG. 2 taken along line B-B, after the annealing operation for D2W bonding, according to an embodiment of the present disclosure.

Referring to FIGS. 1 to 3B, a first wafer 11 can have a plurality of unsingulated bottom dies 21. Each bottom die 21 can include a first integrated circuit 31 formed therein (e.g., transistors, capacitors, resistor, and inductors). Each bottom die 21 can include a first set of operational contacts 41 and a first set of test contacts 51 (or probe pads) exposed on a top surface of each bottom die 21. A plurality of singulated top dies 22 can be attached to the plurality of bottom dies 21, respectively, on the first wafer 11. Each top die 22 can be singulated from a second wafer before a D2W bonding process, where the second wafer is different from the first wafer 11. Each top die 22 can include a second integrated circuit 32 formed therein (e.g., transistors, capacitors, resistor, and inductors). Each top die 22 can include a second set of operational contacts 42 exposed on a bottom surface of each top die 22.

Because the contacts 41, 42, 51 can include or be made of one or more metals that is/are susceptible to oxidation, it can be important to prevent, hinder, and/or remove oxidation from the various contacts 41, 42, 51. Oxidation of a metal can create a surface layer that acts as an insulator or poor conductor, which can create additional or unwanted resistance at contact interfaces, and potential even hinder or prevent functionality of a given contact for providing current flow and/or communication signals. For example, the contacts 41, 42, 51 of the bottom die 21 and/or the top die 22 can include or be made of any suitable metal, including (but not necessarily limited to): copper, aluminum, titanium, titanium nitride, tantalum, tantalum nitride, ruthenium, cobalt, molybdenum, tungsten, niobium, or any combination thereof. In an example embodiment, the contacts 41, 42, 51 can include copper, such that the exposed contacts are exposed copper. Copper is susceptible to rapid oxidation when exposed to ambient air and/or oxygen, to form copper oxide (Cu₂O).

Referring to FIG. 1, a pick-and-place operation can be performed to precisely position the top dies 22 on the bottom dies 21 such that the second set of operational contacts 42 of each top die 22 are aligned with and physically contacting the first set of operational contacts 41 of each bottom die 21, respectively, and such that the first set of test contacts 51 on each bottom die 21 are exposed and not fully covered by each top die 22, respectively. The first set of test contacts 51 on each bottom die 21 can remain exposed for probe testing after the D2W bonding is completed. However, the first set of test contacts 51 on each bottom die 21 can be covered later in a subsequent operation of packaging in some uses or some packaging configurations.

Referring to FIG. 1, many top dies 22 are already placed on many bottom dies 21, respectively, on the first wafer 11. FIG. 1 illustrates a placement operation in motion for a top die 22 being placed on a bottom die 21 on the first wafer 11. Such pick-and-place operation can be performed by a robot or a robotic arm.

Referring to FIG. 3A, optionally, a flux material and/or an adhesive material can be present at the contact interface of the first set of operational contacts 41 and the second set of operational contacts 42, which can aid in retaining the position of the top die 22 on the bottom die 21 after placement and/or can aid in a subsequent bonding operation for a D2W bonding process. For example, the first wafer 11 may be moved and/or transported from one tool to another tool, and/or from one portion of a tool to another portion of the same tool, after the placement of the top dies 22 on the bottom dies 21 and before the completion of a D2W bonding operation. In some embodiments, the first set of operational contacts 41 and the second set of operational contacts 42 can be in direct contact without any intervening material(s), and for example, the top die 22 can be retained in place by an adhesive between the top die 22 and the bottom die 21 that is outside of the first set of operational contacts 41 and the second set of operational contacts 42.

After the placing of the top dies 22 on the bottom dies 21 on the first wafer 11, the first wafer 11 can be transported and placed into a plasma-equipped furnace chamber of a tool, while the top dies 22 remain in place on the bottom dies 21. In a plasma-equipped furnace chamber of a tool, the first wafer 11 can be annealed to induce bonding of the second set of operational contacts 42 of each top die 22 with the first set of operational contacts 41 of each bottom die 21, respectively, in the plasma-equipped furnace chamber while exciting a plasma in the plasma-equipped furnace chamber along with flowing of a chamber gas including nitrogen and hydrogen. The plasma of the chamber gas can prevent or hinder oxidation of exposed metal (e.g., exposed copper) of the first set of test contacts 51 during the annealing.

For example, the first wafer 11 can be transported in a vacuum sealed boat to the plasma-equipped furnace chamber. The first wafer 11 can be loaded into or placed into the plasma-equipped furnace chamber from the boat while maintaining a vacuum to avoid, minimize, or reduce the exposed metals of the first set of test contacts 51 (as well as other components) from being exposed to ambient air and/or oxygen (to prevent or reduce oxidation of the exposed metals). The plasma-equipped furnace chamber can have the capability of heating the first wafer 11 for an annealing operation while also providing a plasma environment in the plasma-equipped furnace chamber or at least within a certain distance from a top surface of the first wafer 11. Before heating, as heating, after heating, or any combination thereof, of the plasma-equipped furnace chamber by one or more furnace elements, the plasma-equipped furnace chamber can transition from a vacuum to having a flow of a chamber gas via one or more gas dispersion elements (e.g., showerhead) and at the same time (or shortly thereafter) initiating a plasma of the chamber gas in the plasma-equipped furnace chamber. The plasma can excite the chamber gas into an energized ionic state in the plasma-equipped furnace chamber or at least within a certain distance from a top surface of the first wafer 11. For example, a chamber gas can include or consist of N₂ and H₂. For example, a chamber gas can include or consist of ammonia (NH₃). The chamber gas can be used alone or along with a carrier gas (e.g., helium, argon, nitrogen, or any combination thereof).

Referring to FIG. 3B, the elevated temperature of the annealing operation in the plasma-equipped furnace chamber can enable atomic diffusion of metal atoms across the contact interface, i.e., the bonding interface where the first set of operational contacts 41 are physically contacting the second set of operational contacts 42. As the metal atoms diffuse across the contact interface, the boundary between the two surfaces of the first set of operational contacts 41 and the second set of operational contacts 42 can disappear forming a seamless connection, as illustrated in FIG. 3B for example.

Referring to FIG. 3B, because the first set of test contacts 51 can be exposed during the transporting of the first wafer 11, while loading the first wafer 11, during temporary storage of the first wafer 11, during the D2W bonding, or any combination thereof, an exposed surface area 53 of the first set of test contacts 51 can be oxidized. By flowing a chamber gas into the plasma-equipped furnace chamber and exciting the chamber gas to generate a plasma of ions from the chamber gas, the energized ions of the chamber gas can bombard the exposed surface area 53 of the first set of test contacts 51 to chemically reduce oxidized portions back to non-oxidized metal and/or hinder or prevent oxidation of the metal. Thus, by providing a plasma of the chamber gas during the annealing, the exposed surface area 53 of the first set of test contacts 51 can be chemically reacted to reduce oxidized portions back to non-oxidized metal and/or the plasma can hinder or prevent oxidation of the metal during the annealing.

In an example embodiment where the first set of operational contacts 41 and the second set of operational contacts 42 include copper, copper-to-copper bonding for a D2W bonding process can be achieved with an annealing temperature in a range of 200° C. to 400° C. In an example embodiment, copper-to-copper bonding for a D2W bonding process can be performed in a plasma-equipped furnace chamber where the chamber gas includes nitrogen and hydrogen, where the chamber gas is flowed at a volumetric flow rate in a range of 100 sccm to 1000 sccm, or less than 500 sccm, where the pressure of the chamber gas in the plasma-equipped furnace chamber is in a range of 1 mTorr to 9 mTorr, or less than 5 mTorr.

Referring to FIG. 4, a plasma-equipped furnace chamber 60 can be configured so that multiple wafers 11A, 11B, 11C can be annealed in a plasma of a chamber gas, according to an embodiment of the present disclosure, for D2W bonding, at the same time. FIG. 4 illustrates an example with three wafers 11A, 11B, 11C in a single plasma-equipped furnace chamber 60. In other embodiments, more than three wafers can be placed into a plasma-equipped furnace chamber for performing a D2W bonding process with annealing in a plasma of the chamber gas.

In some embodiments, optionally, a wafer (or wafers) can be placed in a plasma-equipped furnace chamber to remove surface oxidation from the exposed metal of contacts (as a pre-treatment or cleaning operation) (e.g., causing a reducing reaction to extract oxygen and return oxidized metal back to non-oxidized metal) prior to a pick-and-place operation to ensure that there is a direct metal-to-metal physical contact without any intervening surface oxide layers (or at least minimizing or reducing such surface oxide layers on the exposed metal), using a first annealing of the wafer(s) while exciting a first plasma in the plasma-equipped furnace chamber along with flowing of a first chamber gas. The first chamber gas can include nitrogen and hydrogen. The first chamber gas can include or consist of ammonia (NH₃). The first chamber gas can include or consist of N₂ and H₂. The first annealing in the plasma-equipped furnace chamber can be performed at a temperature in a range of 100° C. to 450° C., at a chamber pressure of 1 mTorr to 9 mTorr, and at a volumetric flow of the first chamber gas in a range of 100 sccm to 1000 sccm, for example.

And then, in some embodiments, after the first annealing for pre-treatment/cleaning, and after the pick-and-place operation of the top dies on the bottom dies of a wafer (or wafers), a second annealing of the wafer(s) can be performed in the plasma-equipped furnace chamber to induce bonding of a second set of operational contacts 42 of each top die 22 with a first set of operational contacts 41 of each bottom die 21 in the plasma-equipped furnace chamber while exciting a second plasma in the plasma-equipped furnace chamber along with flowing of a second chamber gas to reduce and/or hinder oxidation of the metal of a first set of test contacts 51 during the second annealing (as described above regarding FIGS. 1-4).

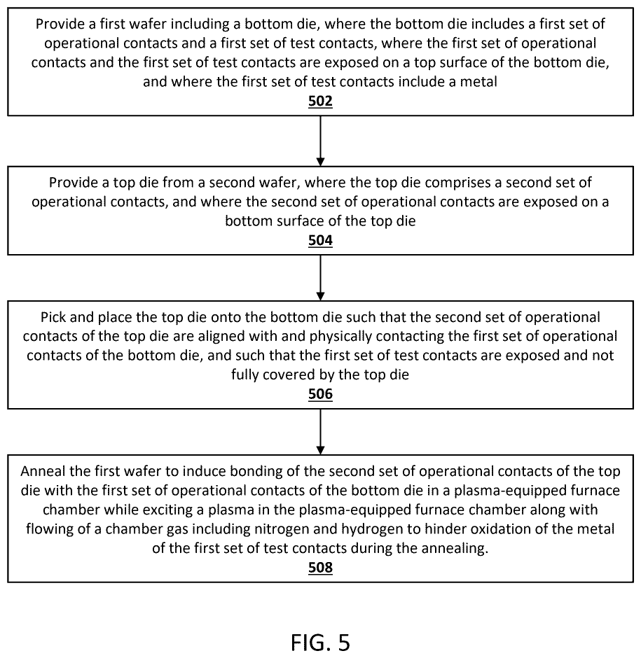

FIGS. 5 to 7 provide some example flowcharts illustrating some example methods that can be used for making the example embodiments described above and shown in FIGS. 1 to 4.

FIG. 5 is a flowchart illustrating a method for manufacturing semiconductor devices according to an embodiment of the present disclosure. In a method for manufacturing semiconductor devices, the method can include providing a first wafer including a bottom die, where the bottom die includes a first integrated circuit formed therein, where the bottom die includes a first set of operational contacts and a first set of test contacts, where the first set of operational contacts and the first set of test contacts are exposed on a top surface of the bottom die, and where the first set of test contacts include a metal (e.g., copper) (box 502).

In a method for manufacturing semiconductor devices, the method can include providing a top die from a second wafer, where the second wafer is different than the first wafer, where the top die includes a second integrated circuit formed therein, where the top die includes a second set of operational contacts, and where the second set of operational contacts are exposed on a bottom surface of the top die (box 504).

In a method for manufacturing semiconductor devices, the method can include picking and placing the top die onto the bottom die such that the second set of operational contacts of the top die are aligned with and physically contacting the first set of operational contacts of the bottom die, and such that the first set of test contacts are exposed and not fully covered by the top die (box 506).

In a method for manufacturing semiconductor devices, the method can include placing the first wafer into a plasma-equipped furnace chamber while the top die is in place on the bottom die (if not already there for prior operation(s)), and annealing the first wafer to induce bonding of the second set of operational contacts of the top die with the first set of operational contacts of the bottom die in the plasma-equipped furnace chamber while exciting a plasma in the plasma-equipped furnace chamber along with flowing of a chamber gas including nitrogen and hydrogen to hinder oxidation of the metal of the first set of test contacts during the annealing (box 508).

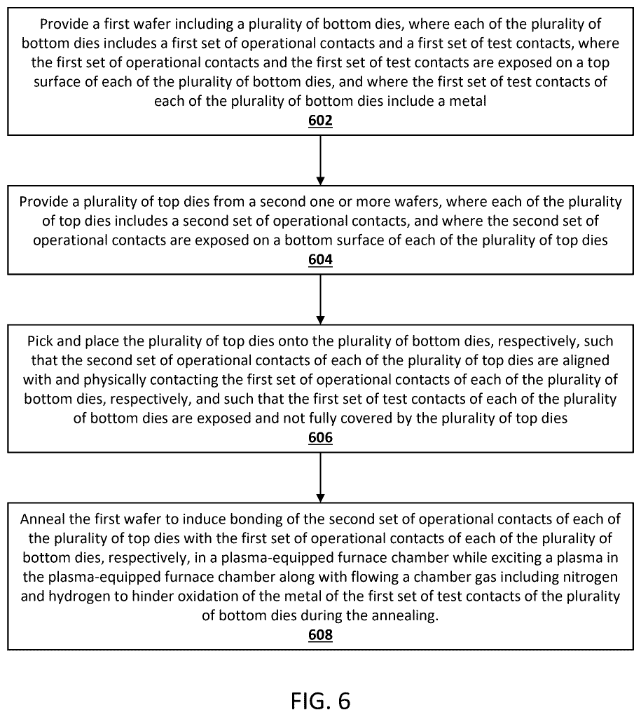

FIG. 6 is a flowchart illustrating a method for manufacturing semiconductor devices according to an embodiment of the present disclosure. In a method for manufacturing semiconductor devices, the method can include providing a first wafer including a plurality of bottom dies, where each of the plurality of bottom dies includes a first integrated circuit formed therein, where each of the plurality of bottom dies includes a first set of operational contacts and a first set of test contacts, where the first set of operational contacts and the first set of test contacts are exposed on a top surface of each of the plurality of bottom dies, and where the first set of test contacts of each of the plurality of bottom dies include a metal (e.g., copper) (box 602).

In a method for manufacturing semiconductor devices, the method can include providing a plurality of top dies from a second one or more wafers, where the second one or more wafers is different than the first wafer, where each of the plurality of top dies includes a second integrated circuit formed therein, where each of the plurality of top dies includes a second set of operational contacts, and where the second set of operational contacts are exposed on a bottom surface of each of the plurality of top dies (box 604).

In a method for manufacturing semiconductor devices, the method can include picking and placing the plurality of top dies onto the plurality of bottom dies, respectively, such that the second set of operational contacts of each of the plurality of top dies are aligned with and physically contacting the first set of operational contacts of each of the plurality of bottom dies, respectively, and such that the first set of test contacts of each of the plurality of bottom dies are exposed and not fully covered by the plurality of top dies (box 606).

In a method for manufacturing semiconductor devices, the method can include placing the first wafer into a plasma-equipped furnace chamber while the plurality of top dies are in place on the plurality of bottom dies (if not already there for prior operation(s)), and annealing the first wafer to induce bonding of the second set of operational contacts of each of the plurality of top dies with the first set of operational contacts of each of the plurality of bottom dies, respectively, in the plasma-equipped furnace chamber while exciting a plasma in the plasma-equipped furnace chamber along with flowing of a chamber gas including nitrogen and hydrogen to hinder oxidation of the metal of the first set of test contacts of the plurality of bottom dies during the annealing (box 608).

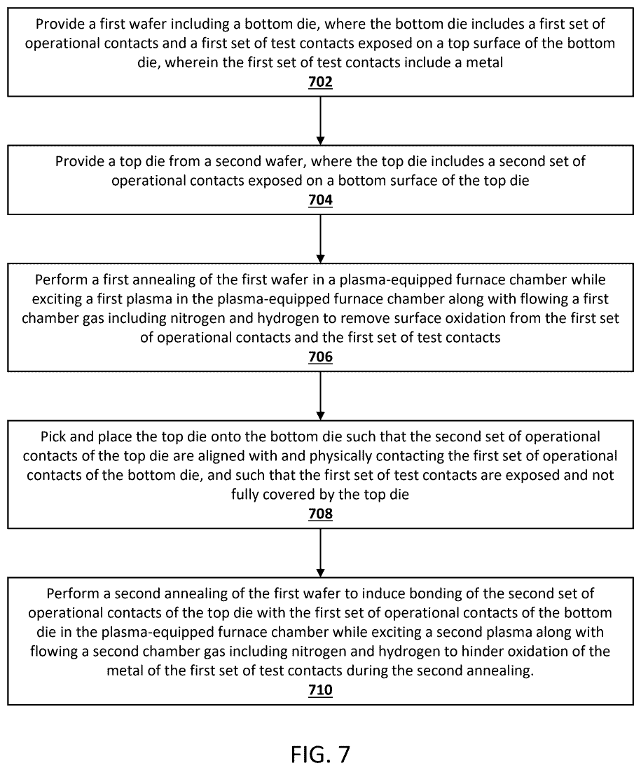

FIG. 7 is a flowchart illustrating a method for manufacturing semiconductor devices according to an embodiment of the present disclosure. In a method for manufacturing semiconductor devices, the method can include providing a first wafer including a bottom die, where the bottom die includes a first integrated circuit formed therein, where the bottom die includes a first set of operational contacts and a first set of test contacts, where the first set of operational contacts and the first set of test contacts are exposed on a top surface of the bottom die, and where the first set of test contacts include a metal (e.g., copper) (box 702).

In a method for manufacturing semiconductor devices, the method can include providing a top die from a second wafer, where the second wafer is different than the first wafer, where the top die includes a second integrated circuit formed therein, where the top die includes a second set of operational contacts, and where the second set of operational contacts are exposed on a bottom surface of the top die (box 704).

In a method for manufacturing semiconductor devices, the method can include placing the first wafer into a plasma-equipped furnace chamber (if not already there for prior operation(s)), and performing a first annealing of the first wafer in the plasma-equipped furnace chamber while exciting a first plasma in the plasma-equipped furnace chamber along with flowing of a first chamber gas including nitrogen and hydrogen to remove surface oxidation from the first set of operational contacts and the first set of test contacts (e.g., as a pre-treat for bonding and/or cleaning prior to D2W bonding of the first set of operational contacts) (box 706).

In a method for manufacturing semiconductor devices, the method can include removing the first wafer from the plasma-equipped furnace chamber (or perhaps not), and picking and placing the top die onto the bottom die such that the second set of operational contacts of the top die are aligned with and physically contacting the first set of operational contacts of the bottom die, and such that the first set of test contacts are exposed and not fully covered by the top die (box 708).

In a method for manufacturing semiconductor devices, the method can include placing the first wafer into the plasma-equipped furnace chamber while the top die is in place on the bottom die (if not already there for prior operation(s)), and performing a second annealing of the first wafer to induce bonding of the second set of operational contacts of the top die with the first set of operational contacts of the bottom die in the plasma-equipped furnace chamber while exciting a second plasma in the plasma-equipped furnace chamber along with flowing of a second chamber gas including nitrogen and hydrogen to hinder oxidation of the metal of the first set of test contacts during the second annealing (box 710).

The embodiments described in FIGS. 5 to 7 may be implemented as further described using FIGS. 1-4 and 8.

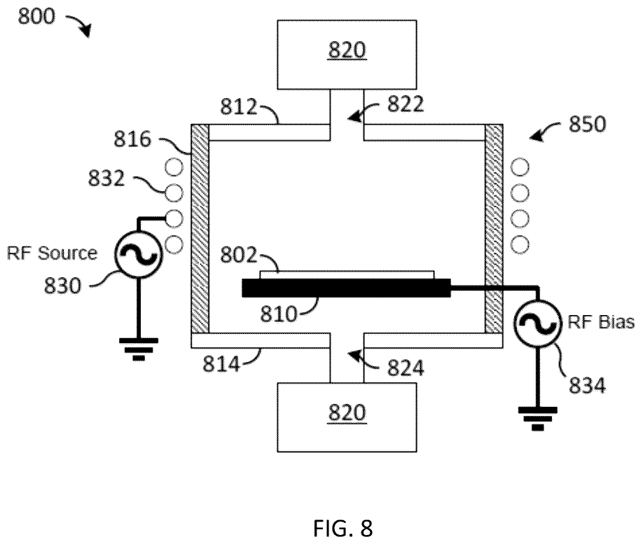

FIG. 8 is a diagram illustrating a plasma-equipped furnace chamber of a tool 800 that can be used in implementing methods of manufacturing semiconductor devices according to some embodiments of the present disclosure. The tool 800 can be used for performing electrical field and plasma processes, such as assisting a reaction using an electric field and/or plasma, as well as providing the flowing and removing of gases in the chamber 850, for example. The tool 800 can have a plasma processing chamber 850 configured to sustain plasma directly above a wafer 802 loaded onto a wafer holder 810. A process gas can be introduced to the plasma processing chamber 850 through a gas inlet 822 and can be pumped out of the plasma processing chamber 850 through a gas outlet 824. The gas inlet 822 and the gas outlet 824 can include a set of multiple gas inlets and gas outlets, respectively. The gas flow rates and chamber pressure can be controlled by a gas flow control system 820 coupled to the gas inlet 822 and the gas outlet 824. The gas flow control system 820 can include various components, such as high-pressure gas canisters, valves (e.g., throttle valves), pressure sensors, gas flow sensors, vacuum pumps, pipes, and electronically programmable controllers, for example. A radio frequency (RF) bias power source 834 and an RF source power source 830 can be coupled to respective electrodes of the plasma processing chamber 850. The wafer holder 810 can also be the electrode coupled to the RF bias power source 834 (e.g., for providing an electrically-biased wafer holder). In various embodiments, the plasma may be powered to be inductively coupled, capacitively coupled, or a hybrid. In an implementation, the RF source power source 830 can be coupled to a helical electrode 832 coiled around a dielectric sidewall 816. In another implementation, the electrode 832 can be placed in other locations such as over the top plate 812 and within the chamber in different combinations. The gas inlet 822 can be an opening in a top plate 812. The gas outlet 824 can be an opening in a bottom plate 814. The top plate 812 and bottom plate 814 can be conductive and electrically connected to the system ground (a reference potential).

The tool 800 is an example only. In various alternative embodiments, the tool 800 can be configured to sustain inductively coupled plasma (ICP) with RF source power coupled to a planar coil over a top dielectric cover, or capacitively coupled plasma (CCP) sustained using a disc-shaped top electrode in the plasma processing chamber 850. Alternately, other suitable configurations such as electron cyclotron resonance (ECR) plasma sources and/or a helical resonator can be used. The RF bias power source 834 can be used to supply continuous wave (CW) or pulsed RF power to sustain the plasma. According to some embodiments, the RF bias power source 834 may not be powered so that the wafer holder 810 is not electrically biased. Gas inlets and gas outlets can be coupled to sidewalls of the plasma processing chamber, and pulsed RF power sources and pulsed DC power sources also can be used in some embodiments. In various embodiments, the RF power, chamber pressure, substrate temperature, gas flow rates and other plasma process parameters can be selected in accordance with respective process recipes. For some embodiments, a remote plasma system and/or a batch system may be used. For example, the wafer holder can be configured to support a plurality of wafers that are spun around a central axis as they pass through different plasma zones.

More example embodiments of the present disclosure are summarized here. Other embodiments can also be understood from the entirety of the specification as well as the claims filed herein.

Example 1. A method of manufacturing semiconductor devices, the method including: providing a first wafer including a bottom die, where the bottom die includes a first integrated circuit formed therein, where the bottom die includes a first set of operational contacts and a first set of test contacts, where the first set of operational contacts and the first set of test contacts are exposed on a top surface of the bottom die, and where the first set of test contacts include a metal; providing a top die from a second wafer, where the second wafer is different than the first wafer, where the top die includes a second integrated circuit formed therein, where the top die includes a second set of operational contacts, and where the second set of operational contacts are exposed on a bottom surface of the top die; picking and placing the top die onto the bottom die such that the second set of operational contacts of the top die are aligned with and physically contacting the first set of operational contacts of the bottom die, and such that the first set of test contacts are exposed and not fully covered by the top die; and annealing the first wafer to induce bonding of the second set of operational contacts of the top die with the first set of operational contacts of the bottom die in a plasma-equipped furnace chamber while exciting a plasma in the plasma-equipped furnace chamber along with flowing of a chamber gas including nitrogen and hydrogen to hinder oxidation of the metal of the first set of test contacts during the annealing.

Example 2. The method of example 1, further including: prior to the annealing, placing the first wafer into the plasma-equipped furnace chamber while the top die is in place on the bottom die; placing a third wafer and a fourth wafer into the plasma-equipped furnace chamber along with the first wafer; and annealing the third wafer and the fourth wafer along with the first wafer.

Example 3. The method of one of examples 1 or 2, where the bottom die is not singulated from the first wafer prior to the annealing, and where the top die is singulated from the second wafer prior to the annealing.

Example 4. The method of one of examples 1 to 3, where the metal contains copper, and where the annealing is performed at temperature in a range of 200° C. to 400° C.

Example 5. The method of one of examples 1 to 4, where the flowing of the chamber gas is at a pressure less than 5 mTorr.

Example 6. The method of one of examples 1 to 5, where the flowing of the chamber gas is at a pressure in a range of 1 mTorr to 9 mTorr.

Example 7. The method of one of examples 1 to 6, where the flowing of the chamber gas is at a volumetric flow rate less than 500 sccm.

Example 8. A method of manufacturing semiconductor devices, the method including: providing a first wafer including a plurality of bottom dies, where each of the plurality of bottom dies includes a first integrated circuit formed therein, where each of the plurality of bottom dies includes a first set of operational contacts and a first set of test contacts, where the first set of operational contacts and the first set of test contacts are exposed on a top surface of each of the plurality of bottom dies, and where the first set of test contacts of each of the plurality of bottom dies include a metal; providing a plurality of top dies from a second one or more wafers, where the second one or more wafers is different than the first wafer, where each of the plurality of top dies includes a second integrated circuit formed therein, where each of the plurality of top dies includes a second set of operational contacts, and where the second set of operational contacts are exposed on a bottom surface of each of the plurality of top dies; picking and placing the plurality of top dies onto the plurality of bottom dies, respectively, such that the second set of operational contacts of each of the plurality of top dies are aligned with and physically contacting the first set of operational contacts of each of the plurality of bottom dies, respectively, and such that the first set of test contacts of each of the plurality of bottom dies are exposed and not fully covered by the plurality of top dies; and annealing the first wafer to induce bonding of the second set of operational contacts of each of the plurality of top dies with the first set of operational contacts of each of the plurality of bottom dies, respectively, in a plasma-equipped furnace chamber while exciting a plasma in the plasma-equipped furnace chamber along with flowing of a chamber gas including nitrogen and hydrogen to hinder oxidation of the metal of the first set of test contacts of the plurality of bottom dies during the annealing.

Example 9. The method of example 8, further including: prior to the annealing, placing the first wafer into the plasma-equipped furnace chamber while the plurality of top dies are in place on the plurality of bottom dies; placing a third wafer and a fourth wafer into the plasma-equipped furnace chamber along with the first wafer; and annealing the third wafer and the fourth wafer along with the first wafer.

Example 10. The method of one of examples 8 or 9, where the plurality of bottom dies are not singulated from the first wafer prior to the annealing, and where the plurality of top dies are singulated from the second one or more wafers prior to the annealing.

Example 11. A method of manufacturing semiconductor devices, the method including: providing a first wafer including a bottom die, where the bottom die includes a first integrated circuit formed therein, where the bottom die includes a first set of operational contacts and a first set of test contacts, where the first set of operational contacts and the first set of test contacts are exposed on a top surface of the bottom die, and where the first set of test contacts include a metal; providing a top die from a second wafer, where the second wafer is different than the first wafer, where the top die includes a second integrated circuit formed therein, where the top die includes a second set of operational contacts, and where the second set of operational contacts are exposed on a bottom surface of the top die; performing a first annealing of the first wafer in a plasma-equipped furnace chamber while exciting a first plasma in the plasma-equipped furnace chamber along with flowing of a first chamber gas including nitrogen and hydrogen to remove surface oxidation from the first set of operational contacts and the first set of test contacts; picking and placing the top die onto the bottom die such that the second set of operational contacts of the top die are aligned with and physically contacting the first set of operational contacts of the bottom die, and such that the first set of test contacts are exposed and not fully covered by the top die; and performing a second annealing of the first wafer to induce bonding of the second set of operational contacts of the top die with the first set of operational contacts of the bottom die in the plasma-equipped furnace chamber while exciting a second plasma in the plasma-equipped furnace chamber along with flowing of a second chamber gas including nitrogen and hydrogen to hinder oxidation of the metal of the first set of test contacts during the second annealing.

Example 12. The method of example 11, further including: prior to the first annealing, placing the first wafer into the plasma-equipped furnace chamber; after the first annealing, removing the first wafer from the plasma-equipped furnace chamber; and prior to the second annealing, placing the first wafer into the plasma-equipped furnace chamber while the top die is in place on the bottom die.

Example 13. The method of one of examples 11 or 12, further including: prior to the second annealing, placing the first wafer into the plasma-equipped furnace chamber while the top die is in place on the bottom die; placing a third wafer and a fourth wafer into the plasma-equipped furnace chamber along with the first wafer; and performing the second annealing for the third wafer and the fourth wafer along with the first wafer.

Example 14. The method of one of examples 11 to 13, where the metal contains copper, and where the second annealing is performed at temperature in a range of 200° C. to 400° C., and where the first annealing is performed at temperature in a range of 100° C. to 450° C.

Example 15. The method of one of examples 11 to 14, where the flowing of the first chamber gas is at a pressure in a range of 1 mTorr to 9 mTorr, and at a volumetric flow in a range of 100 sccm to 1000 sccm.

Example 16. The method of one of examples 11 to 15, where the flowing of the second chamber gas is at a pressure less than 5 mTorr.

Example 17. The method of one of examples 11 to 16, where the flowing of the second chamber gas is at a pressure in a range of 1 mTorr to 9 mTorr.

Example 18. The method of one of examples 11 to 17, where the flowing of the second chamber gas is at a volumetric flow rate less than 500 sccm.

Example 19. The method of one of examples 11 to 18, where the flowing of the second chamber gas is at a volumetric flow in a range of 100 sccm to 1000 sccm.

Example 20. The method of one of examples 11 to 19, where the first chamber gas includes of ammonia, and where the second chamber gas includes N2 and H2.

An advantage of using plasma during annealing can be that plasma can be done with a much lower pressure and/or volumetric flow rate of a reducing gas in the chamber as compared to not using plasma and simply flowing the chamber gas into a furnace during annealing. Plasma can provide higher reactivity for a reducing gas in the chamber at a relatively lower pressure and/or volumetric flow rate, as compared to no plasma. Hence, an advantage of using some embodiments of the present disclosure can be hindering or preventing metal oxidation and/or cleaning/removing/reducing oxidation of a metal contact during annealing using a chamber gas (e.g., nitrogen and hydrogen containing gas) while using less chamber gas because of the plasma as compared to a conventional process that does not implement the use of plasma. Lower chemical consumption for D2W bonding process flows can reduce waste and reduce manufacturing costs, which are advantages that can be provided by implementing an embodiment of the present disclosure.

An advantage of using some embodiments of the present disclosure can be improving manufacturing throughput and efficiency (e.g., reducing bottlenecks) by processing multiple wafers in a single plasma-equipped furnace chamber during a pre-treatment/cleaning and/or bonding for D2W bonding process flows using annealing combined with plasma in accordance with an embodiment of the present disclosure. Also, processing multiple wafers at the same time in a same plasma-equipped furnace chamber not only improves throughput, it also reduces chemical consumption (for reducing gas) and energy consumption (for the furnace and other components of the tool), which are advantages that can be provided by implementing an embodiment of the present disclosure.

Batch processes can reduce cost of ownership and cost of operation, as well as improve overall manufacturability for D2W solutions, which are advantages that can be provided by implementing an embodiment of the present disclosure.

Tests performed using probe pads or test contacts that are without a surface layer of oxidation, or that have minimal or reduced surface oxidation, provide more accurate, more reliable, and overall better test results when assessing semiconductor devices after a D2W bonding process, which are advantages that can be provided by implementing an embodiment of the present disclosure.

While illustrative and example embodiments have been described with reference to illustrative drawings, this description is not intended to be construed in a necessarily limiting sense. Various modifications and combinations of the illustrative and example embodiments, as well as other embodiments, can be apparent to persons skilled in the pertinent art upon referencing the present disclosure. It is therefore intended that the appended claims encompass any and all of such modifications, equivalents, or embodiments.

What is claimed is:

1. A method of manufacturing semiconductor devices, the method comprising:
providing a first wafer comprising a bottom die, wherein the bottom die comprises a first integrated circuit formed therein, wherein the bottom die comprises a first set of operational contacts and a first set of test contacts, wherein the first set of operational contacts and the first set of test contacts are exposed on a top surface of the bottom die, and wherein the first set of test contacts include a metal;
providing a top die from a second wafer, wherein the second wafer is different than the first wafer, wherein the top die comprises a second integrated circuit formed therein, wherein the top die comprises a second set of operational contacts, and wherein the second set of operational contacts are exposed on a bottom surface of the top die;
picking and placing the top die onto the bottom die such that the second set of operational contacts of the top die are aligned with and physically contacting the first set of operational contacts of the bottom die, and such that the first set of test contacts are exposed and not fully covered by the top die; and
annealing the first wafer to induce bonding of the second set of operational contacts of the top die with the first set of operational contacts of the bottom die in a plasma-equipped furnace chamber while exciting a plasma in the plasma-equipped furnace chamber along with flowing of a chamber gas including nitrogen and hydrogen to hinder oxidation of the metal of the first set of test contacts during the annealing.

2. The method of claim 1, further comprising:
prior to the annealing, placing the first wafer into the plasma-equipped furnace chamber while the top die is in place on the bottom die;
placing a third wafer and a fourth wafer into the plasma-equipped furnace chamber along with the first wafer; and
annealing the third wafer and the fourth wafer along with the first wafer.

3. The method of claim 1, wherein the bottom die is not singulated from the first wafer prior to the annealing, and wherein the top die is singulated from the second wafer prior to the annealing.

4. The method of claim 1, wherein the metal contains copper, and wherein the annealing is performed at temperature in a range of 200° C. to 400° C.

5. The method of claim 1, wherein the flowing of the chamber gas is at a pressure less than 5 mTorr.

6. The method of claim 1, wherein the flowing of the chamber gas is at a pressure in a range of 1 mTorr to 9 mTorr.

7. The method of claim 1, wherein the flowing of the chamber gas is at a volumetric flow rate less than 500 sccm.

8. A method of manufacturing semiconductor devices, the method comprising:
providing a first wafer comprising a plurality of bottom dies, wherein each of the plurality of bottom dies comprises a first integrated circuit formed therein, wherein each of the plurality of bottom dies comprises a first set of operational contacts and a first set of test contacts, wherein the first set of operational contacts and the first set of test contacts are exposed on a top surface of each of the plurality of bottom dies, and wherein the first set of test contacts of each of the plurality of bottom dies include a metal;
providing a plurality of top dies from a second one or more wafers, wherein the second one or more wafers is different than the first wafer, wherein each of the plurality of top dies comprises a second integrated circuit formed therein, wherein each of the plurality of top dies comprises a second set of operational contacts, and wherein the second set of operational contacts are exposed on a bottom surface of each of the plurality of top dies;
picking and placing the plurality of top dies onto the plurality of bottom dies, respectively, such that the second set of operational contacts of each of the plurality of top dies are aligned with and physically contacting the first set of operational contacts of each of the plurality of bottom dies, respectively, and such that the first set of test contacts of each of the plurality of bottom dies are exposed and not fully covered by the plurality of top dies; and
annealing the first wafer to induce bonding of the second set of operational contacts of each of the plurality of top dies with the first set of operational contacts of each of the plurality of bottom dies, respectively, in a plasma-equipped furnace chamber while exciting a plasma in the plasma-equipped furnace chamber along with flowing of a chamber gas including nitrogen and hydrogen to hinder oxidation of the metal of the first set of test contacts of the plurality of bottom dies during the annealing.

9. The method of claim 8, further comprising:
prior to the annealing, placing the first wafer into the plasma-equipped furnace chamber while the plurality of top dies are in place on the plurality of bottom dies;
placing a third wafer and a fourth wafer into the plasma-equipped furnace chamber along with the first wafer; and
annealing the third wafer and the fourth wafer along with the first wafer.

10. The method of claim 8, wherein the plurality of bottom dies are not singulated from the first wafer prior to the annealing, and wherein the plurality of top dies are singulated from the second one or more wafers prior to the annealing.

11. A method of manufacturing semiconductor devices, the method comprising:
providing a first wafer comprising a bottom die, wherein the bottom die comprises a first integrated circuit formed therein, wherein the bottom die comprises a first set of operational contacts and a first set of test contacts, wherein the first set of operational contacts and the first set of test contacts are exposed on a top surface of the bottom die, and wherein the first set of test contacts include a metal;
providing a top die from a second wafer, wherein the second wafer is different than the first wafer, wherein the top die comprises a second integrated circuit formed therein, wherein the top die comprises a second set of operational contacts, and wherein the second set of operational contacts are exposed on a bottom surface of the top die;
performing a first annealing of the first wafer in a plasma-equipped furnace chamber while exciting a first plasma in the plasma-equipped furnace chamber along with flowing of a first chamber gas including nitrogen and hydrogen to remove surface oxidation from the first set of operational contacts and the first set of test contacts;
picking and placing the top die onto the bottom die such that the second set of operational contacts of the top die are aligned with and physically contacting the first set of operational contacts of the bottom die, and such that the first set of test contacts are exposed and not fully covered by the top die; and
performing a second annealing of the first wafer to induce bonding of the second set of operational contacts of the top die with the first set of operational contacts of the bottom die in the plasma-equipped furnace chamber while exciting a second plasma in the plasma-equipped furnace chamber along with flowing of a second chamber gas including nitrogen and hydrogen to hinder oxidation of the metal of the first set of test contacts during the second annealing.

12. The method of claim 11, further comprising:
prior to the first annealing, placing the first wafer into the plasma-equipped furnace chamber;
after the first annealing, removing the first wafer from the plasma-equipped furnace chamber; and
prior to the second annealing, placing the first wafer into the plasma-equipped furnace chamber while the top die is in place on the bottom die.

13. The method of claim 11, further comprising:
prior to the second annealing, placing the first wafer into the plasma-equipped furnace chamber while the top die is in place on the bottom die;
placing a third wafer and a fourth wafer into the plasma-equipped furnace chamber along with the first wafer; and
performing the second annealing for the third wafer and the fourth wafer along with the first wafer.

14. The method of claim 11, wherein the metal contains copper, and wherein the second annealing is performed at temperature in a range of 200° C. to 400° C., and wherein the first annealing is performed at temperature in a range of 100° C. to 450° C.

15. The method of claim 11, wherein the flowing of the first chamber gas is at a pressure in a range of 1 mTorr to 9 mTorr, and at a volumetric flow in a range of 100 sccm to 1000 sccm.

16. The method of claim 11, wherein the flowing of the second chamber gas is at a pressure less than 5 mTorr.

17. The method of claim 11, wherein the flowing of the second chamber gas is at a pressure in a range of 1 mTorr to 9 mTorr.

18. The method of claim 11, wherein the flowing of the second chamber gas is at a volumetric flow rate less than 500 sccm.

19. The method of claim 11, wherein the flowing of the second chamber gas is at a volumetric flow in a range of 100 sccm to 1000 sccm.

20. The method of claim 11, wherein the first chamber gas includes of ammonia, and wherein the second chamber gas includes N2 and H2.
